(19) United States
(12) Patent Application Publication
(10) Pub. No.: US 2024/0128125 A1
(43) Pub. Date: Apr. 18, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Winnie Victoria Wei-Ning Chen, Hsinchu County (TW); Chia-Ling Pai, Taichung City (TW); Pang-Yen Tsai, Hsin-Chu (TW)

(73) Assignee: Taiwan Semiconductor Manufacturing Company, Ltd., Hsinchu (TW)

(21) Appl. No.: 18/162,714

(22) Filed: Feb. 1, 2023

Related U.S. Application Data
(60) Provisional application No. 63/415,665, filed on Oct. 13, 2022.

(51) Int. Cl. H01L 21/8234; H01L 29/06; H01L 29/423; H01L 29/66

(52) U.S. Cl. CPC H01L 21/823412; H01L 21/823431; H01L 29/0673; H01L 29/42392; H01L 29/66545; H01L 29/66553

(57) ABSTRACT

A method of forming a semiconductor device includes providing a substrate having a recess, and growing an epitaxial feature in the recess. The method of growing the epitaxial feature includes: (a) growing a sub-layer of the epitaxial feature; (b) selectively etching the sub-layer of the epitaxial feature while providing a first UV radiation; and (c) repeating step (a) and step (b) alternately multiple times.

### CROSS REFERENCE TO RELATED APPLICATION

This application claims the priority benefit of U.S. provisional application Ser. No. 63/415,665, filed on Oct. 13, 2022. The entirety of the above-mentioned patent application is hereby incorporated by reference herein and made a part of specification.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6A, 6B, 7A, 7B, 8A, 8B, 9A, 9B, 10, 11, 12, 13, 14A, 14B, 14C, 15A, 15B, 15C, 16, 17, 18, 19A, 19B, 19C and 19D illustrate varying views of a method of forming a semiconductor device in accordance with some embodiments.

FIG. 20 is a schematic view of a semiconductor fabrication apparatus in accordance with some embodiments.

FIG. 21 illustrates a flow chart of a method of forming a semiconductor device in accordance with some embodiments.

FIG. 22A to FIG. 22B illustrate a flow chart of a method of forming a semiconductor device in accordance with some embodiments.

FIG. 23A to FIG. 23B illustrate a flow chart of a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure may be used to form epitaxial features of gate stacks suitable for use in planar bulk metal-oxide-semiconductor field-effect transistors (MOSFETs), multi-gate transistors (planar or vertical) such as FinFET devices, gate-all-around (GAA) devices, Omega-gate (a-gate) devices, or Pi-gate (H-gate) devices, as well as strained-semiconductor devices, silicon-on-insulator (SOI) devices, partially-depleted SOI devices, fully-depleted SOI devices, or other devices as known in the art. In addition, embodiments disclosed herein may be employed in the formation of p-type and/or n-type devices. One of ordinary skill may recognize other embodiments of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

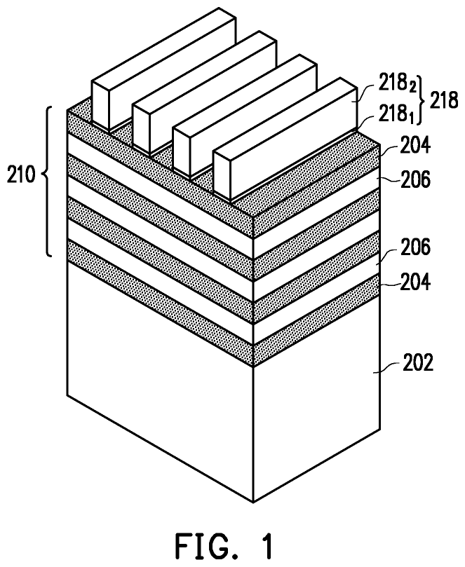

FIG. 1 to FIG. 19D illustrate varying views of a method of forming a semiconductor device in accordance with some embodiments. The semiconductor device illustrated in the following embodiments may be, for example but not limited to, a multi-gate device. As used herein, the term “multi-gate device” is used to describe a device (e.g., a semiconductor transistor) that has at least some gate material disposed on multiple sides of at least one channel of the device. In some examples, the multi-gate device may be referred to as a gate-all-around (GAA) device having a gate material disposed on four sides of at least one channel member of the device. The channel member may be referred to as “nanosheet” or “nanowire” which is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example but not limited to, a cylindrical in shape or substantially rectangular cross-section. The method is merely an example, and is not intended to limit the present disclosure beyond what is explicitly recited in the claims. Additional steps may be provided before, during, and after method, and some of the steps described can be moved, replaced, or eliminated for additional embodiments of method. Additional features may be added in the semiconductor device depicted in FIG. 1 to FIG. 19D and some of the features described below can be replaced, modified, or eliminated in other embodiments of the semiconductor device.

FIG. 1 to FIG. 5 illustrate perspective views of stages of forming a semiconductor device. Referring to FIG. 1, a substrate 202 is provided. In some embodiments, the substrate 202 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof. The substrate 202 may include various doped regions (e.g., p-type well and/or n-type well) depending on design requirements. In some embodiments, the doped regions may be doped with p-type or n-type dopants. The doped regions may be configured for an n-type device, or alternatively, configured for a p-type device. In some embodiments, an anti-punch-through (APT) implantation is performed on a top portion of the substrate 202 to form an APT region. The conductivity type of the dopants implanted in the APT region is the same as that of the doped regions (or wells). The APT region may extend under the subsequently formed epitaxial features, and are used to reduce the leakage from the epitaxial features to the substrate 202. The epitaxial features are referred to “strained layers” or “source/drain regions” in some examples. Source/drain region(s) may refer to a source or a drain, individually or collectively dependent upon the context. For clarity, the doped regions and the APT region are not illustrated in FIG. 1 and subsequent drawings.

In some embodiments, a semiconductor stack 210 is formed over the substrate 202. The semiconductor stack 210 includes first blanket layers 204 and second blanket layers 206 stacked alternately. The first and second blanket layers are referred to as “first and second layers”, “first and second materials”, “first and second compositions” or “first and second semiconductor materials” in some examples. The first blanket layers 204 and second blanket layers 206 include different materials. In some embodiments, the first blanket layers 204 are SiGe layers having a germanium percentage in the range between about 15 wt % and 40 wt %, and the second blanket layers 206 are Si layers free of germanium. In other embodiments, either of the first blanket layers 204 and second blanket layers 206 may include other materials such as germanium, a compound semiconductor (e.g., silicon carbide, gallium arsenide, gallium phosphide, indium phosphide, indium arsenide, or indium antimonide), an alloy semiconductor (e.g., SiGe, GaAsP, AlInAs, AlGaAs, InGaAs, GaInP, or GaInAsP), the like, or a combination thereof.

The first blanket layers 204 and the second blanket layers 206 have materials with different etching selectivities. In some embodiments, the first blanket layers 204 and the second blanket layers 206 are formed by an epitaxial growth process, such as a molecular beam epitaxy (MBE) process, a metalorganic chemical vapor deposition (MOCVD) process, or the like. In the case, the first blanket layers 204 are epitaxial SiGe layers, and the second blanket layers 206 are epitaxial Si layers. In some embodiments, the first and second blanket layers 204 and 206 are substantially dopant-free (i.e., having an extrinsic dopant concentration from about 0 cm⁻³ to about 1×10¹⁷ cm⁻³), where for example, no intentional doping is performed during the epitaxial growth process. In other embodiments, the first blanket layers 204 and the second blanket layers 206 are formed by a suitable deposition, such as chemical vapor deposition (CVD), atomic layer deposition (ALD), or the like. In the case, the first blanket layers 204 are poly-SiGe layers, and the second blanket layers 206 are poly-Si layers.

In the illustrated embodiment, the bottom layer and the top layer of the semiconductor stack 210 are SiGe layers. However, the disclosure is not limited thereto. In other embodiments (not shown), the bottom layer of the semiconductor stack 210 is a Si layer and the top layer of the semiconductor stack 210 is a SiGe layer. It is noted that four layers of first blanket layers 204 and three layers of second blanket layers 206 are illustrated in FIG. 1, which is for illustrative purposes only and not intended to be limiting beyond what is specifically shown in the drawings. Specifically, any number of epitaxial layers may be formed in the semiconductor stack 210; the number of layers depending on the desired number of channel regions for the device 200.

In some embodiments, each of the first blanket layers 204 and the second blanket layers 206 has a thickness ranging from about 5 nm to about 15 nm. As described in more detail below, the second blanket layer 206 may serve as channel region(s) for a subsequently formed multi-gate device and its thickness chosen based on device performance considerations. The first blanket layer 204 may be configured to define a gap between adjacent channel region(s) for a subsequently formed multi-gate device and its thickness chosen based on device performance considerations.

Still referring to FIG. 1, mask strips 218 are formed over the semiconductor stack 210. In some embodiments, a mask layer is formed on the semiconductor stack 210. The mask layer may include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. In some embodiments, the mask layer includes a first mask layer and a second mask layer over the second mask layer. For example, the first mask layer is a pad oxide layer made of a silicon oxide, which may be formed by a thermal oxidation. The second mask layer is made of a silicon nitride (SiN), which is formed by chemical vapor deposition (CVD), low pressure CVD (LPCVD), plasma enhanced CVD (PECVD), physical vapor deposition (PVD), atomic layer deposition (ALD), or a suitable process. The mask layer is then patterned into the mask strips 218 by using photolithography and etching processes. In some embodiments, each of the mask strips 218 includes a first mask pattern 218₁ and a second mask pattern 218₂ over the first mask pattern 218₁.

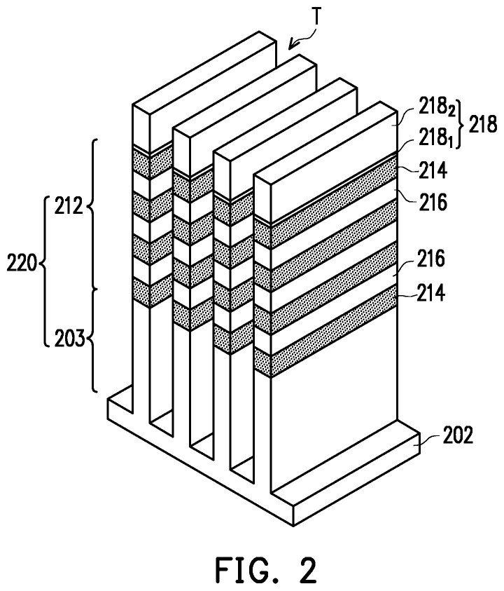

Referring to FIG. 2, the semiconductor stack 210 and the substrate 202 are patterned by using the mask strips 218 as a mask, so as to form semiconductor strips 220 separated by trenches T. The patterning process includes an etching process, such as a dry etching or the like. As shown in FIG. 2, the trenches T extend into the substrate 202, and have lengthwise directions parallel to each other. Herein, the semiconductor strips 212 are referred to as “hybrid fins” in some examples. In some embodiments, each of the semiconductor strips 220 includes a fin 203 protruding from the substrate 202, and a nanosheet stack 212 on the fin 203. In some embodiments, the nanosheet stack 212 includes first nanosheets 214 and second nanosheets 216 stacked alternately. The nanosheets are referred to as “nanowires” or “semiconductor nanosheets” in some examples. In some embodiments, the first nanosheets are referred to as “sacrificial portions”, “dummy portions” or “dummy regions” which will be subsequently removed and replaced by a metal gate structure, and the second nanosheets are referred to as “channel members”, “channel portions” or “channel regions” which will serve as semiconductor channels. Although only four semiconductor strips 220 are illustrated in FIG. 2, the embodiments of the present disclosure are not limited thereto. In other embodiments, the number of the semiconductor strips 220 may be adjusted as needed. The adjacent semiconductor strips 220 may have the same width or different widths.

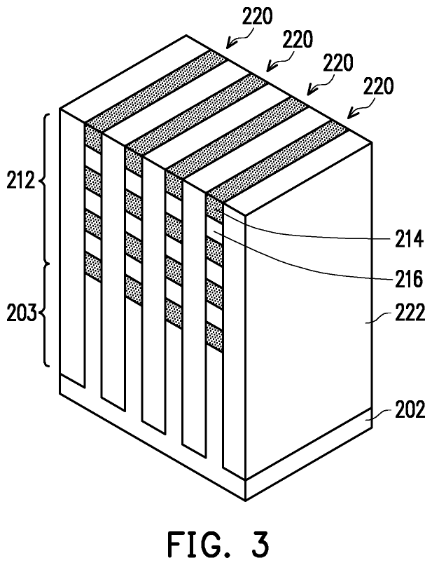

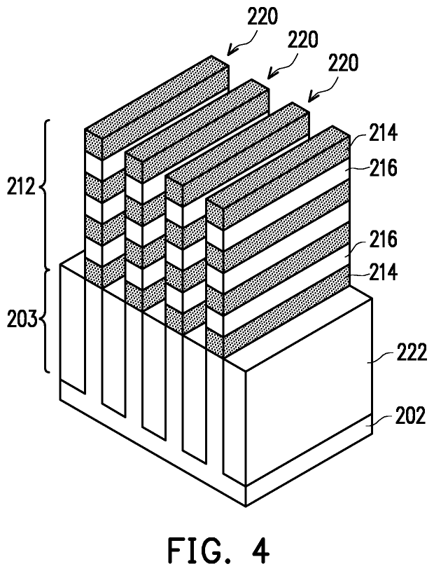

Referring to FIG. 3 and FIG. 4, insulating regions 222 are formed in the trenches T between the semiconductor strips 220. In some embodiments, an insulating material is formed on the substrate 202, covering the semiconductor strips 220 and filling up the trenches T. In addition to the semiconductor strips 220, the insulating material further covers the mask strips 218. The insulating material may include silicon oxide, silicon nitride, silicon oxynitride, a spin-on dielectric material, or a low-k material. The low-k material has a dielectric constant less than 3.9, less than 3, less than 2.5, or even less. The insulating material may be formed by flowable chemical vapor deposition (FCVD), high-density-plasma chemical vapor deposition (HDP-CVD), sub-atmospheric CVD (SACVD), or spin-on process. A planarization process may be performed to remove a portion of the insulating material and the mask strips 218, until the semiconductor strips 220 are exposed. In the case, as shown in FIG. 3, the top surfaces of the semiconductor strips 220 are substantially coplanar with the top surfaces of the insulating regions 222. In some embodiments, the planarization process includes a chemical mechanical polish (CMP), an etching back process, the like, or a combination thereof.

Referring to FIG. 3 and FIG. 4, the insulating regions 222 are recessed, until the semiconductor strips 220 protrude from top surfaces of the remaining insulating regions 222. Specifically, after the recessing operation, the top surfaces of the insulating regions 222 are lower than the top surfaces of the semiconductor strips 220 and the nanosheet stacks 212 are exposed by the insulating regions 222. The top surfaces of the insulating regions 222 may be substantially coplanar with or lower than bottom surfaces of the nanosheet stacks 212. Further, the top surfaces of the insulating regions 222 may have a flat surface, a convex surface, a concave surface (such as dishing), or a combination thereof. In some embodiments, the insulating regions 222 are recessed by using an appropriate etching process, such as a wet etching process with hydrofluoric acid (HF), a dry etching process, or a combination thereof. In some embodiments, a height difference between the top surfaces of the semiconductor strips 220 and the top surfaces of the insulating regions 222 ranges from about 30 nm to about 100 nm. The insulating regions 222 are referred to as “isolation strips”, “shallow trench isolation (STI) regions” or “deep trench isolation (DTI) regions” in some examples.

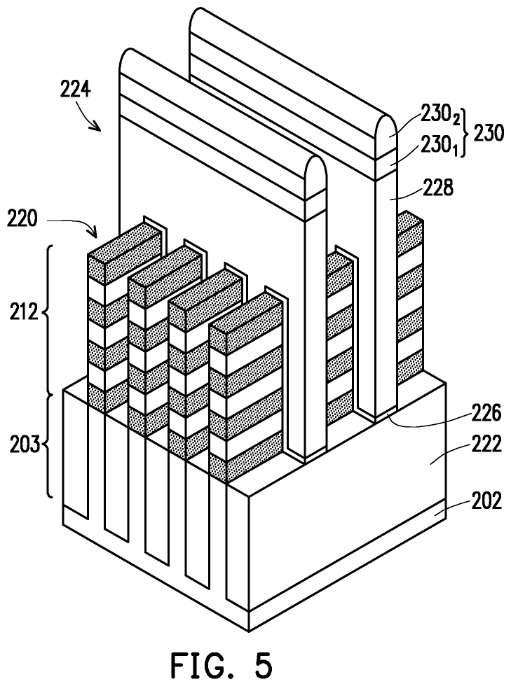

Referring to FIG. 5, at least two dummy gate stack 224 are formed across portions of the nanosheet stacks 212 and portions of the insulating regions 222. The dummy gate stacks 224 may extend along a direction different from (e.g., perpendicular to) the extending direction of the nanosheet stacks 212. The dummy gate stacks 224 define the channel regions of the GAA devices. Each dummy gate stack 224 includes a dummy gate dielectric layer 226 and a dummy gate electrode layer 228 over the dummy gate dielectric layer 226. In some embodiments, a dummy gate dielectric material and a dummy gate electrode material are blanket-formed over the semiconductor strips 220. The dummy gate dielectric material and the dummy gate electrode material are deposited using CVD, LPCVD, PECVD, PVD, ALD, or a suitable process. A mask layer 230 is formed over the dummy gate electrode material. The mask layer 230 may include a dielectric material, such as silicon oxide, silicon nitride, SiON, SiC, SiCN, SiCON, the like, or a combination thereof. Other materials such as a low-k material may be applicable. The low-k material has a dielectric constant less than 3.9, less than 3, less than 2.5, or even less. In some embodiments, the mask layer 230 includes a first mask layer 230₁ (e.g., silicon oxide layer) and a second mask layer 230₂ (e.g., silicon nitride layer) over the first mask layer 230₁. Thereafter, the dummy gate dielectric material and dummy gate electrode material are patterned into the dummy gate stacks 224 by using the mask layer 230 as a mask. The mask layer 230 is regarded as part of the dummy gate stack 224 in some examples.

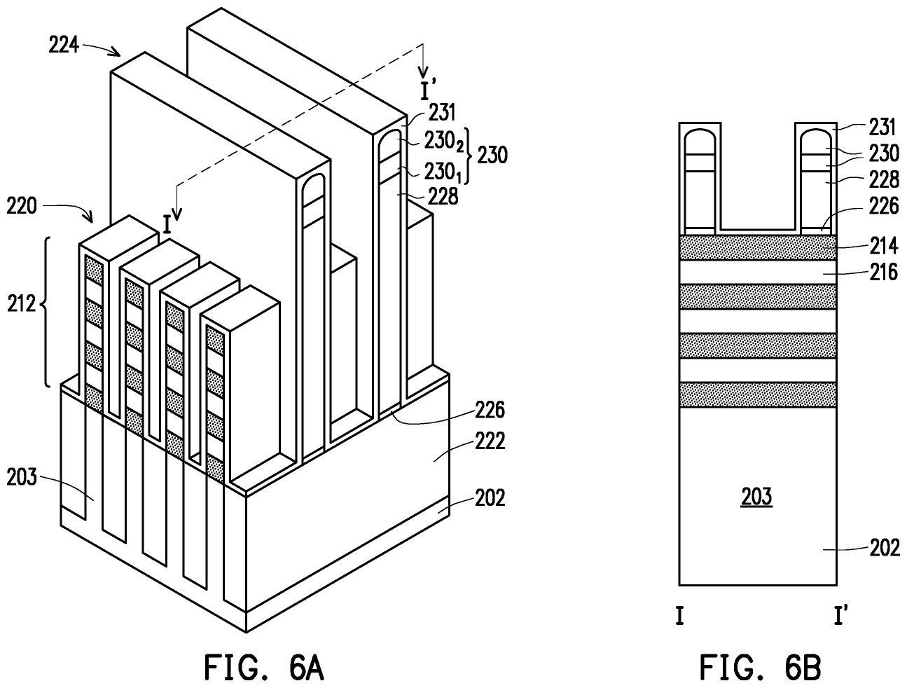

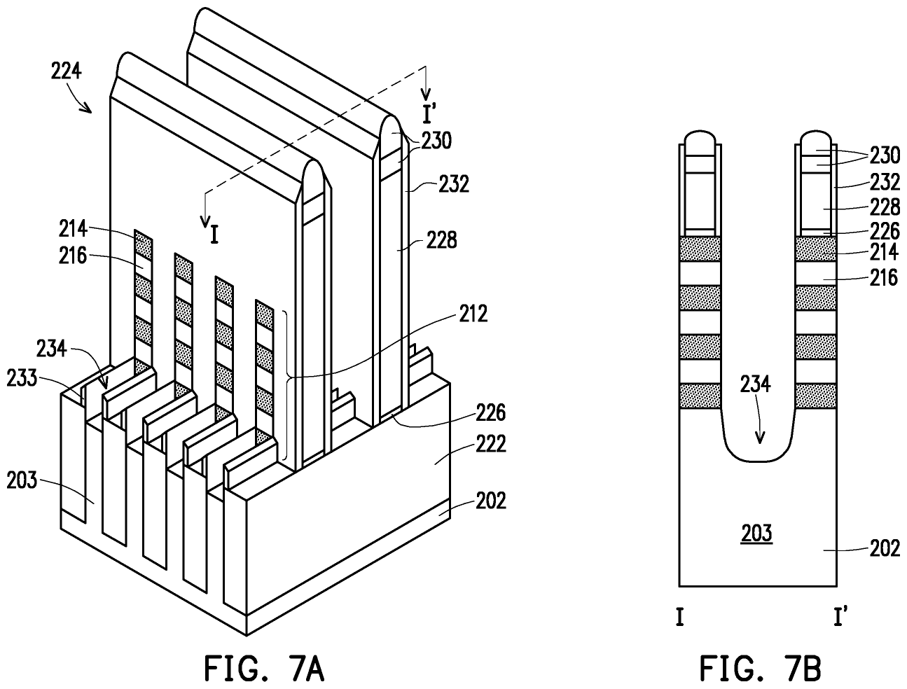

Referring to FIG. 6A, FIG. 6B, FIG. 7A and FIG. 7B, spacers 232 are formed on sidewalls of the dummy gate stacks 224 and sidewalls of the nanosheet stacks 212 by depositing a spacer material 231 and followed by an anisotropic etching. In some embodiments, the spacers 232 include a dielectric material, such as silicon oxide, silicon nitride, SiON, SiC, SiCN, SiCON, or a combination thereof. Other materials such as a low-k material may be applicable. The low-k material has a dielectric constant less than 3.9, less than 3, less than 2.5, or even less. Although the spacers 232 illustrated in FIG. 7A and FIG. 7B have a single-layer structure, the embodiments of the present disclosure are not limited thereto. In other embodiments, the spacers 232 may have a multi-layer structure. For example, the spacers 232 may include a silicon oxide layer and a silicon nitride layer on the silicon oxide layer.

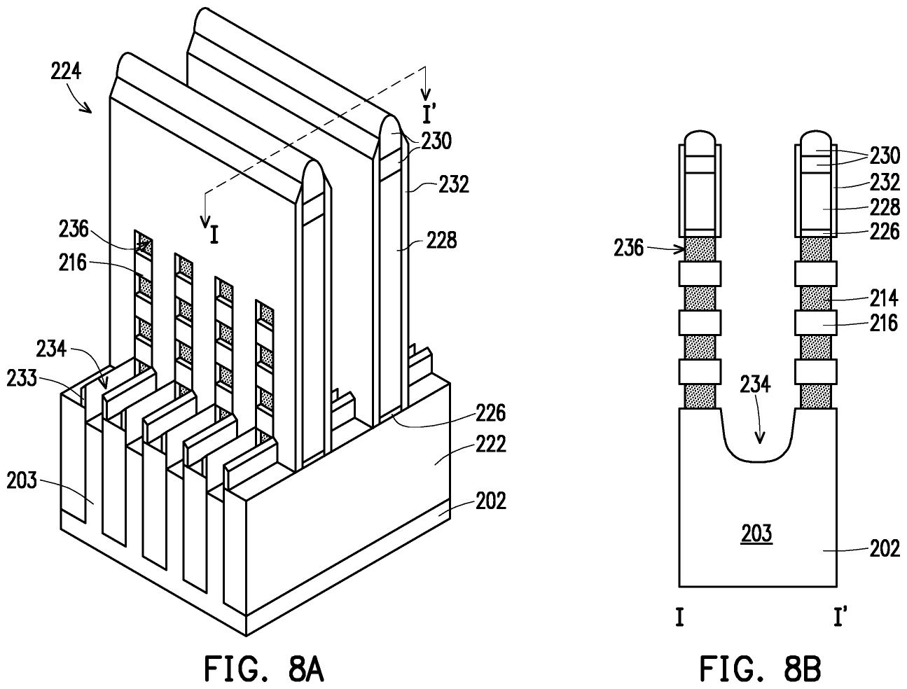

Upon the spacer forming operation, the dummy gate stacks 224 and the spacers 232 cover portions of the nanosheet stacks 212, and expose the portions of the nanosheet stacks 212. As shown in FIG. 8A and FIG. 8B, the exposed portions of the nanosheet stacks 212 are removed and the underlying fins 203 are recessed to form recesses 234. In other words, the end portions of the nanosheet stacks 212 are entirely removed and portions of the fins 203 are further removed. The recesses 234 are referred to as “source/drain (S/D) recesses” in some examples. In some embodiments, the end portions of the nanosheet stacks 212 may be removed by an anisotropic etching process, an isotropic etching process, or a combination thereof. In some embodiments, the top surfaces of the recesses 234 are lower than the top surfaces of the insulating regions 222. In some embodiments, the spacers 232 on the nanosheet stacks 212 are partially removed during the recess forming operation, and the remaining spacers 233 are left standing over and aligned to the edges of insulating regions 222, with the recesses 234 formed therebetween, as shown in FIG. 7A. In many embodiments, the method of forming the recesses 234 includes performing a suitable etching process, such as a dry etching process, a wet etching process, or an RIE process.

Referring to FIG. 8A and FIG. 8B, portions of the first nanosheets 214 are laterally recessed. In some embodiments, the portions of the first nanosheets 214 exposed by the recesses 234 are removed, and thus, cavities 236 are respectively formed between the second nanosheets 216. In some embodiments, the first nanosheets 214 are laterally recessed by a wet etching, a dry etching, or a combination thereof. For example, the first nanosheets 214 may be selectively etched by using a wet etchant including, for example but not limited to, ammonium hydroxide (NH₄OH), tetramethylammonium hydroxide (TMAH), ethylenediamine pyrocatechol (EDP), or potassium hydroxide (KOH) solutions. In other embodiments, before laterally recessing the portions of the first nanosheets 214, the end portions of the first nanosheets 214 exposed by the recesses 234 may be selectively oxidized, so as to increase the etching selectivity between the first and second nanosheets 214 and 216. In other embodiments, the oxidation process may be performed by exposing to a wet oxidation process, a dry oxidation process, or a combination thereof. The chemical used in the oxidation process may include H₂SO₄ or the like.

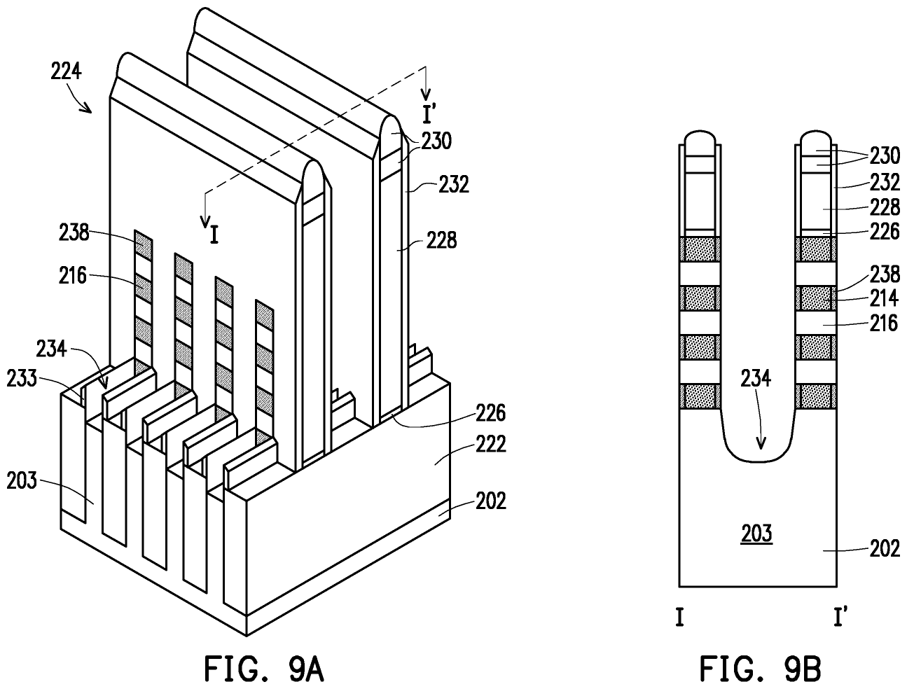

Referring to FIG. 8A, FIG. 8B, FIG. 9A and FIG. 9B, inner spacers 238 are formed in the cavities 236. In some embodiments, an inner spacer material is formed on the substrate 202. In some embodiments, the inner spacer material conformally covers the recesses 234 and the spacers 232 on the dummy gate stacks 224, and further fills in the cavities 236 to reduce the size of the cavities 236 or completely fill in the cavities 236. In some embodiments, the inner spacer material includes silicon oxide, silicon nitride, silicon carbide, silicon carbide nitride, silicon oxide carbide, silicon carbide oxynitride, and/or other suitable dielectric materials, and may be formed by ALD or a suitable method. In other embodiments, the inner spacer material includes a low-k material having a dielectric constant less than 3.9, less than 3, less than 2.5, or even less. Thereafter, the inner spacer material is partially removed to form inner spacers 238 in the cavities 236. In some embodiments, the inner spacer material layer is partially removed by a plasma dry etching or a suitable method. Generally, the plasma dry etching etches a layer in wide and flat areas faster than a layer in concave (e.g., holes, grooves and/or slits) portions. Thus, the remaining inner spacer material forms the inner spacers 238 inside the cavities 236.

Referring to FIG. 10, liner layers 235 are formed in bottoms of the recesses 234, respectively. In some embodiments, the liner layers 235 include Si, Ge, SiGe, the like, or a combination thereof. In some embodiments, the liner layers 235 are formed by an epitaxial growth process and are grown from the bottoms of the recesses 234.

Referring to FIG. 10 to FIG. 15C, epitaxial features 240 are epitaxially grown in the recesses 234 on the liner layers 235. In some embodiments, the liner layers 235 are beneficial for forming the epitaxial features 240 in the recesses 234 because the liner layers 235 improve good interfaces for epitaxially growing the epitaxial features 240. In some embodiments, the epitaxial features 240 include Si, SiGe, Ge, III-V epitaxial films with doping C, P, As, and/or B. For example, when the epitaxial features 240 are provided for a p-type device, the liner layers 235 may be silicon and the epitaxial features 240 may include SiGe, SiGeB, Ge, GeSn, or the like. In other embodiments, when the epitaxial features 240 are provided for an n-type device, the liner layers 235 may be silicon and the epitaxial features 240 may include silicon, SiC, SiCP, SiP, or the like.

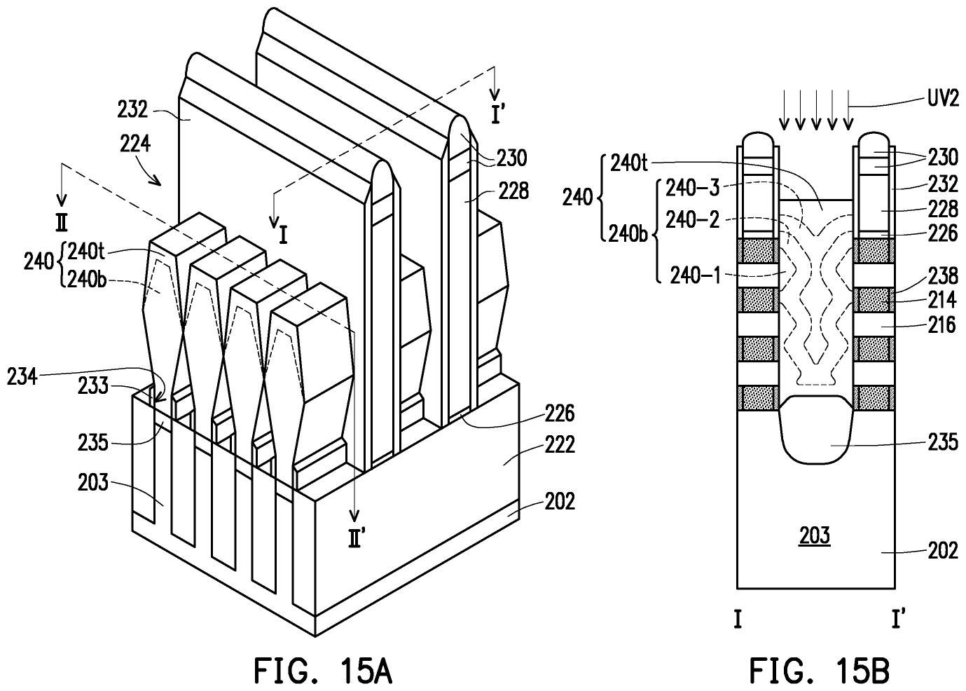

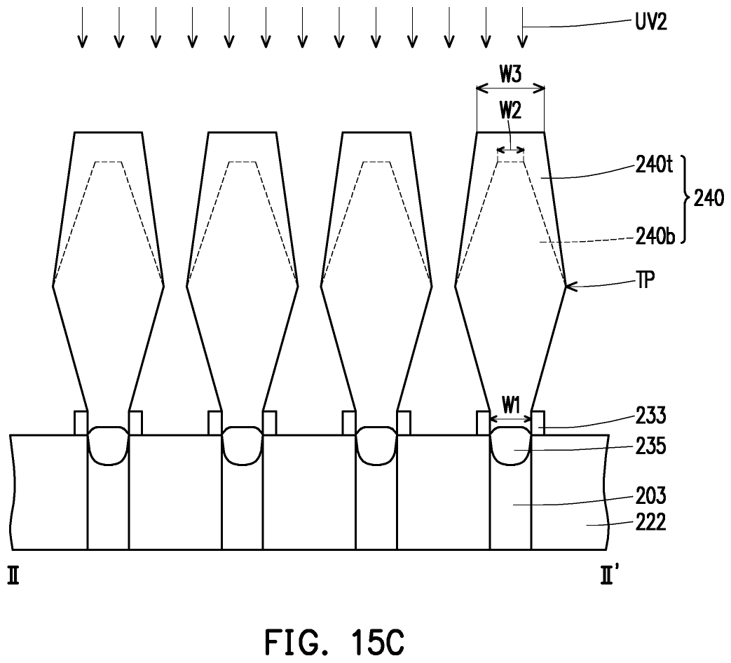

In some embodiments, the epitaxial features 240 are used to strain or stress the second nanosheets (which may be referred to as channel members) 216 and the fins 203. Herein, the epitaxial features may be referred to as “epitaxial layers”, “S/D regions” or “highly doped low resistance materials” in some examples. In some embodiments, the epitaxial features 240 include source regions disposed at one side of the dummy gate stack 224 and drain regions disposed at another side of the dummy gate stack 224. The source regions cover ends of the fins 203, and the drain regions cover opposite ends of the fins 203. The epitaxial features 240 are abutted and electrically connected to the second nanosheets 216, while the epitaxial features 240 are electrically isolated from the first nanosheets 214 by the inner spacers 238. In some embodiments, as shown in FIG. 15B, the epitaxial features 240 extend beyond the top surfaces of the nanosheet stacks 212 (see FIG. 7A), and the adjacent epitaxial features 240 at the same side are formed to separate from each other with the novel epitaxial method with UV illumination of the disclosure, which will be described in details below. In the disclosure, the conventional blocking wall for prevent the adjacent epitaxial features 240 from merging is not required, and the shapes of the epitaxial features 240 are well controlled with the novel epitaxial method with UV illumination of the disclosure.

Referring to FIG. 10, a first sub-layer 240-1 of the epitaxial feature is grown in each of the recesses 234. In some embodiments, the first sub-layer 240-1 is selectively grown on sidewalls of the second nanosheets 216 (e.g., Si nanosheets) exposed by the recesses 234 and on the top surfaces of the liner layers 235. The first sub-layer 240-1 may be discontinuous at this stage. In some embodiments, the precursors or source gases for the epitaxial growth process include a carrier gas (e.g., H₂, N₂, or the like), a silicon-containing precursor (e.g., SiH₄, SiCl₂H₂, Si₂H₆, or the like), a germanium-containing precursor (e.g., GeH₄ or the like), a dopant precursor (e.g., PH₃, AsH₃, B₂H₆ or the like), or a combination thereof. In some embodiments, the first sub-layer 240-1 of the epitaxial feature in each of the recesses 234 is grown under an optional zeroth UV radiation UV0. That is, the zeroth UV radiation UV0 is optional and may be omitted as needed. In some embodiments, the zeroth UV radiation UV0 has a wavelength ranging from about 100 nm to 615 nm with a proton energy from about 2.0 eV to 12.4 eV, and the UV source (lamp/laser) power ranges from about zero to 10 W/m². The zeroth UV radiation UV0 may be provided at a direction normal to a top surface of the substrate.

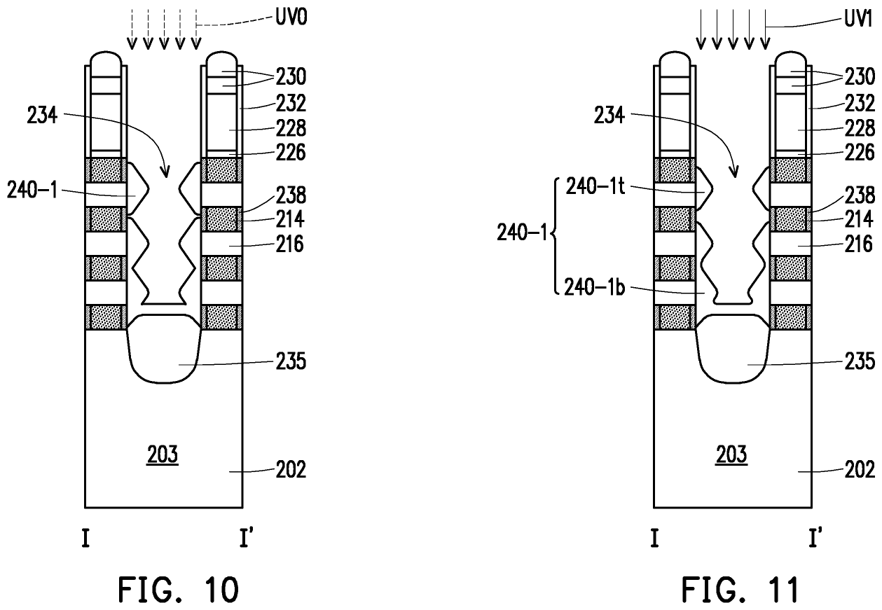

Referring to FIG. 11, the first sub-layer 240-1 of the epitaxial feature is selectively etched under a first UV radiation UV1. In some embodiments, the etching gases for the etching process include a carrier gas (e.g., H₂, N₂, or the like), a halogen-based gas (e.g., Cl₂, CHF₃, CH₃F, C₄F₈, CF₄, SF₆, CF₃Cl, or the like), or a combination thereof. The UV radiation may cause different etching rates during the etching process. In some embodiments, the first UV radiation UV1 has a wavelength ranging from about 100 nm to 615 nm with a proton energy from about 2.0 eV to 12.4 eV, and the UV source (lamp/laser) power ranges from about 10 W/m² to 10,000 W/m². The first UV radiation UV1 may be provided at a direction normal to a top surface of the substrate. The power of the first UV radiation UV1 is greater than the power of the zeroth UV radiation UV0. Under the first UV radiation UV1, the upper portion of the first sub-layer 240-1 is subjected to more radiation and therefore etched at a faster rate, while the lower portion of the first sub-layer 240-1 is subjected to less radiation and therefore etched at a slower rate. Specifically, under the UV illumination, the upper portion the sub-layer 240-1 is removed more while the lower portion the sub-layer 240-1 is removed less, and thus, a wide-top recess is provided for the following step. The step of FIG. 10 and the step FIG. 11 constitutes a cycle of the cyclic deposition and etching process.

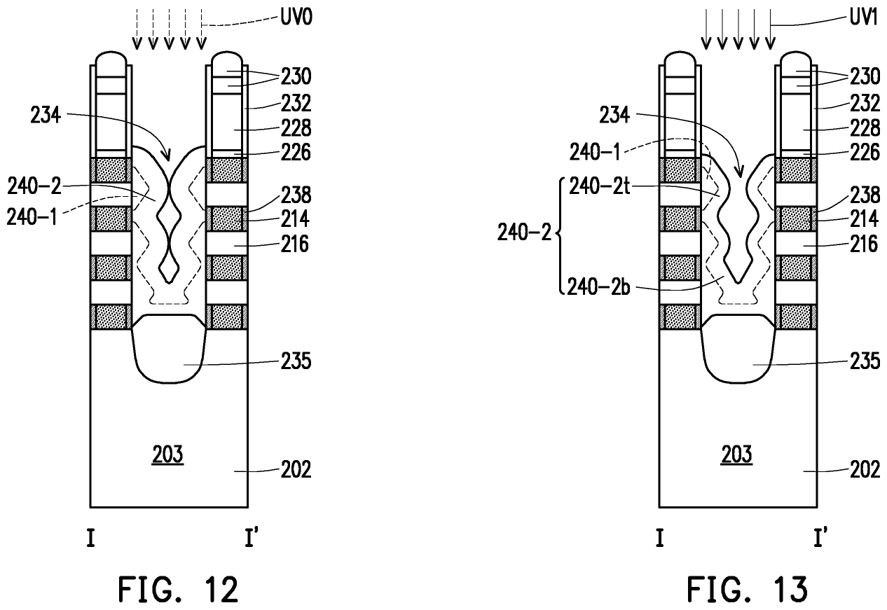

Referring to FIG. 12 to FIG. 13, the steps similar to those described in FIG. 10 to FIG. 11 are performed. In some embodiments, as shown in FIG. 12, a second sub-layer 240-2 of the epitaxial feature is grown in each of the recesses 234 on the first sub-layer 240-1. In some embodiments, the second sub-layer 240-2 is selectively grown on the first sub-layer 240-1 exposed by the recesses 234. The second sub-layer 240-2 may be continuous at this stage. In some embodiments, the precursors or source gases for the epitaxial growth process include a carrier gas (e.g., H₂, N₂, or the like), a silicon-containing precursor (e.g., SiH₄, SiCl₂H₂, Si₂H₆, or the like), a germanium-containing precursor (e.g., GeH₄ or the like), a dopant precursor (e.g., PH₃, AsH₃, B₂H₆ or the like), or a combination thereof. In some embodiments, the second sub-layer 240-2 of the epitaxial feature in each of the recesses 234 is grown under an optional zeroth UV radiation UV0. That is, the zeroth UV radiation UV0 is optional and may be omitted as needed. In some embodiments, the zeroth UV radiation UV0 has a wavelength ranging from about 100 nm to 615 nm with a proton energy from about 2.0 eV to 12.4 eV, and the UV source (lamp/laser) power ranges from about zero to 10 W/m².

Referring to FIG. 13, the second sub-layer 240-1 of the epitaxial feature is selectively etched under a first UV radiation UV1. In some embodiments, the etching gases for the etching process include a carrier gas (e.g., H₂, N₂, or the like), a halogen-based gas (e.g., Cl₂, CHF₃, CH₃F, C₄F₈, CF₄, SF₆, CF₃Cl, or the like), or a combination thereof. The UV radiation may cause different etching rates during the etching process. In some embodiments, the first UV radiation UV1 has a wavelength ranging from about 100 nm to 615 nm with a proton energy from about 2.0 eV to 12.4 eV, and the UV source (lamp/laser) power ranges from about 10 to 10,000 W/m². The power of the first UV radiation UV1 is greater than the power of the zeroth UV radiation UV0. Under the first UV radiation UV1, the upper portion of the second sub-layer 240-2 is subjected to more radiation and therefore etched at a faster rate, while the lower portion of the second sub-layer 240-2 is subjected to less radiation and therefore etched at a slower rate. Specifically, under the UV illumination, the upper portion the second sub-layer 240-2 is removed more while the lower portion the second sub-layer 240-2 is removed less, and thus, a wide-top recess is provided for the following operation.

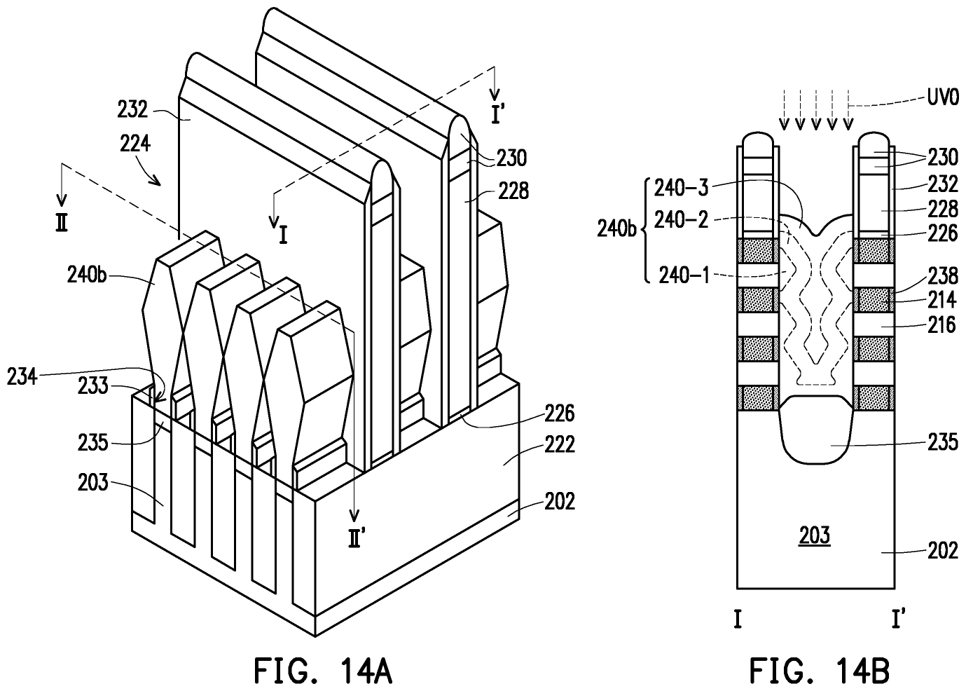

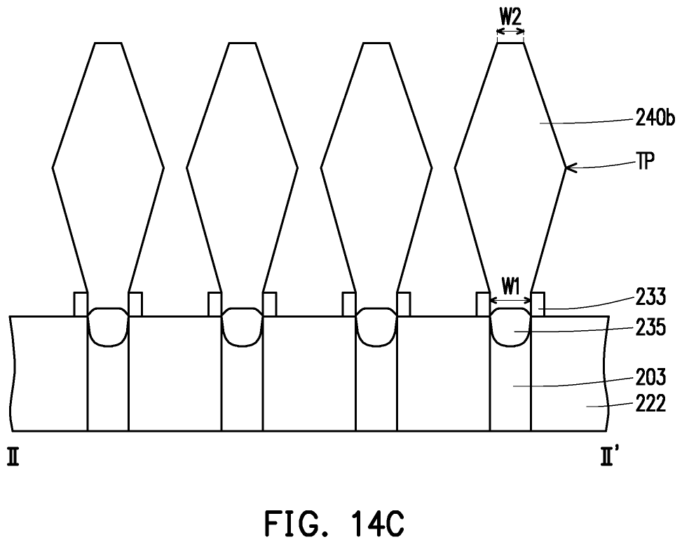

Referring to FIG. 14A to FIG. 14C, a step similar to that described in FIG. 12 is performed. In some embodiments, as shown in FIG. 14A and FIG. 14B, a third sub-layer 240-3 of the epitaxial feature is grown in each of the recesses 234 on the second sub-layer 240-2. In some embodiments, the third sub-layer 240-3 is grown on the second sub-layer 240-2 exposed by the recesses 234. The third sub-layer 240-3 may fill up each of the recesses 234 at this stage. In some embodiments, the precursors or source gases for the epitaxial growth process include a carrier gas (e.g., H₂, N₂, or the like), a silicon-containing precursor (e.g., SiH₄, SiCl₂H₂, Si₂H₆, or the like), a germanium-containing precursor (e.g., GeH₄ or the like), a dopant precursor (e.g., PH₃, AsH₃, B₂H₆ or the like), or a combination thereof. In some embodiments, the third sub-layer 240-3 of the epitaxial feature in each of the recesses 234 is grown under an optional zeroth UV radiation UV0. That is, the zeroth UV radiation UV0 is optional and may be omitted as needed. In some embodiments, the zeroth UV radiation UV0 has a wavelength ranging from about 100 nm to 615 nm with a proton energy from about 2.0 eV to 12.4 eV, and the UV source (lamp/laser) power ranges from about zero to 10 W/m². The step of selectively etching the third sub-layer 240-3 under a first UV radiation UV1 may be omitted when the third sub-layer 240-3 fills up the corresponding recess 234.

In some embodiments, deposition and etching processes are performed multiple times, until the recesses 234 are filled with the first to third sub-layers 240-1 to 204-3, as shown in FIG. 14A and FIG. 14B. In some embodiments, as shown in FIG. 14C, the first to third sub-layers 240-1 to 204-3 constitute a bottom epitaxial feature 240b. In some embodiments, the bottom epitaxial feature 240b has a diamond-like shape having a turning point TP on a sidewall thereof. In some embodiments, the top width W2 is less than the bottom width W1 of the bottom epitaxial feature 240b. The two adjacent bottom epitaxial features 240b are separated from each other.

The above embodiments in which the deposition and etching processes are performed three times are provided for illustration purposes, and are not construed as limiting the present disclosure. For example, the deposition and etching processes are performed m times, until recesses are completely filled with sub-layers, wherein m is 2-10.

Referring to FIG. 15A to FIG. 15C, the bottom epitaxial feature 240b is selectively growing in a z-direction under a second UV radiation UV2. The UV radiation may cause different growth rates during the epitaxial process. In some embodiments, the second UV radiation UV2 has a wavelength ranging from about 100 nm to 615 nm with a proton energy from about 2.0 eV to 12.4 eV, and the UV source (lamp/laser) power ranges from about 10 to 10,000 W/m². The second UV radiation UV2 may be provided at a direction normal to a top surface of the substrate. The power of the second UV radiation UV2 may be the same or different from the power of the first UV radiation UV1. Under the second UV radiation UV2, the top of the epitaxial feature 240b is subjected to more radiation and therefore grown at a faster rate, while the bottom of the epitaxial feature 240b is not subjected to the radiation and therefore maintain intact without epitaxial growing. The UV radiation is provided to promote growth in an upward direction and therefore increase the thickness of the bottom epitaxial feature 240b. The increased portion is labelled as a top epitaxial feature 240t. Accordingly, the top epitaxial feature 240t is grown on the bottom epitaxial feature 240b.

Specifically, the source gas byproducts such as hydrogen and chlorine may adhere to the target surface, which may be referred to herein as passivating the surface. The byproducts can inhibit the epitaxial growth of the epitaxy feature from the passivated surface. To address this passivating of the surface, in some embodiments, the method includes providing UV radiation (e.g., UV2) incident the surface. The UV radiation can remove the byproducts (e.g., Cl, H) from the target surface (e.g., Si) or from portions of the target surface. The removal of the byproducts can generate dangling bonds, which serve as nucleation sites for the epitaxial growth. For example, the UV radiation can reduce chlorine (free of combined chlorine compounds (chloramines)) into easily removed byproducts leaving dangling bonds where the chlorine was attached to the surface. At UV wavelengths, the radiation may produce photochemical reactions that dissociate chlorine to form hydrochloric acid. After UV exposure, the byproducts can then be removed from the surface and subsequently the chamber.

In view of the above, the UV radiation (e.g., UV1) enhances top etching and therefore provide a wide-top recess for epitaxially growing void-free epitaxial features. Besides, the UV radiation (e.g., UV2) may selectively remove source gas byproducts (Cl, H atoms) from the target surface (e.g., bottom epitaxial feature) and therefore enhance z-direction growth. Moreover, the UV radiation (e.g., UV2) may remove Si atom nucleation on spacers and therefore improve selectivity growth on the desired epitaxial regions. The UV radiation (e.g., UV2) may remove 0 atoms from Si nanosheet and pre-clean the desired epitaxial regions.

In some embodiments, as shown in FIG. 15C, the bottom epitaxial feature 240b and the top epitaxial feature 240t constitute an epitaxial feature 240. In some embodiments, the epitaxial feature 240 has a diamond-like shape having a turning point TP at a sidewall thereof. In some embodiments, the top width W3 is equal to or greater than the bottom width W1 of the epitaxial feature 240. The two adjacent epitaxial features 240 are separated from each other.

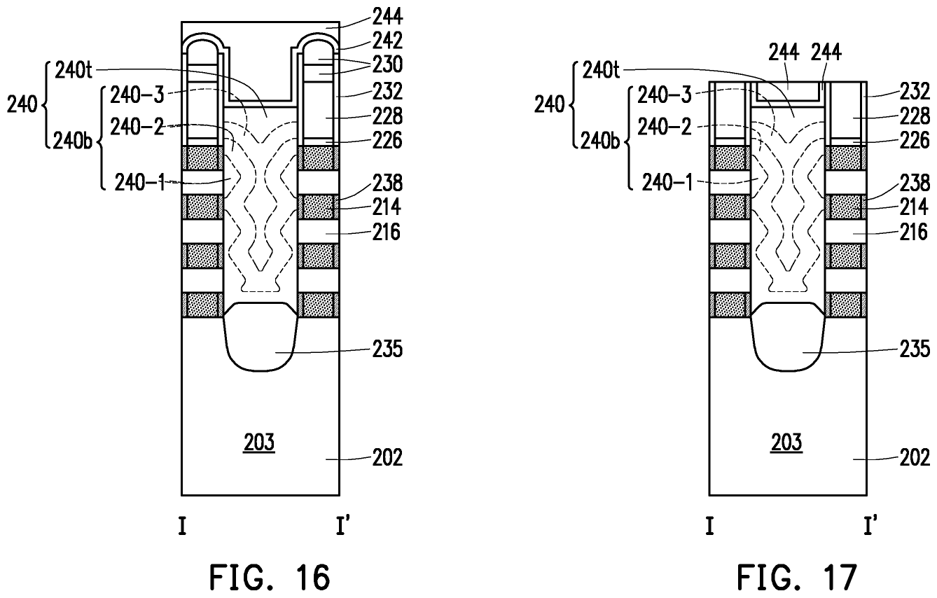

Referring to FIG. 16, a contact etch stop layer (CESL) 242 is formed over the epitaxial features 240. In some embodiments, the CESL 242 conformally covers the sidewalls of the epitaxial features 240, and the sidewalls of the spacers 232 and 233. The CESL 242 may include silicon nitride, silicon oxynitride, silicon nitride with oxygen (O) or carbon (C) elements, metal oxide such as Al₂O₃, the like, or a combination thereof, and may be formed by CVD, PVD, ALD, or a suitable process.

Thereafter, an interlayer dielectric (ILD) layer 244 is formed over the CESL 242. In some embodiments, the ILD layer 244 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. In some other embodiments, the ILD layer 244 includes a low-k material. The low-k material has a dielectric constant less than 3.9, less than 3, less than 2.5, or even less. Examples of the low-k material include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), the like, or a combination thereof. In other embodiments, the ILD layer 244 may have a single-layer structure or a multi-layer structure. In some embodiments, the ILD layer 244 is formed by FCVD, CVD, HDPCVD, SACVD, spin-on process, sputtering, or a suitable process.

Referring to FIG. 17, a planarization process such as CMP is performed to planarize the topography of the structure. In some embodiments, the ILD layer 244, the CESL layer 242, the spacers 232 are partially removed and the mask layer 230 is entirely removed, until the top surface of the dummy gate electrode layer 228 is exposed. In some embodiments, the top surface of the dummy gate electrode layer 228 is substantially flushed with the top surfaces of the ILD layer 244, the CESL layer 242 and the spacers 232.

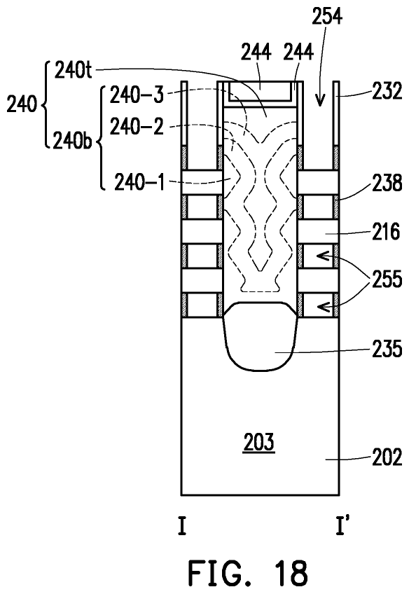

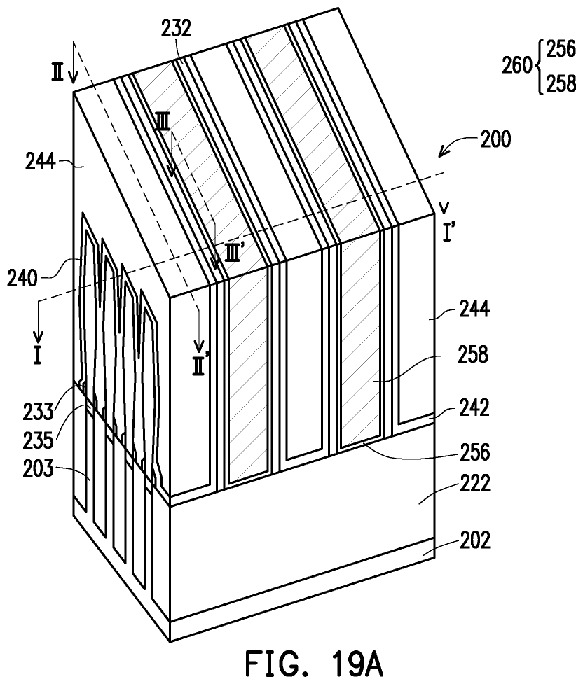

Referring to FIG. 18, the dummy gate stacks 224 (each including a dummy gate electrode layer 228 and a dummy gate dielectric layer 226) are removed to form gate trenches 254. The ILD layer 244 and the CESL layer 242 protect the epitaxial features 240 during the removal of the dummy gate stacks 224. The dummy gate stacks 224 may be removed using plasma dry etching and/or wet etching. When the dummy gate electrode layer 228 is polysilicon and the ILD layer 244 is silicon oxide, a wet etchant such as a TMAH solution may be used to selectively remove the dummy gate electrode layer. The dummy gate dielectric layer 226 is then removed using plasma dry etching and/or wet etching.

Still referring to FIG. 18, channel members (or called channel regions) are defined for the GAA device 200. In some embodiments, an etching process is performed to remove the first nanosheets 214. In the case, the first nanosheets 214 may be completely removed to form gaps 255 between the second nanosheets 216, as shown in FIG. 18. Accordingly, the second nanosheets 216 are separated from each other by the gaps 255. In addition, the bottommost second nanosheet 216 may also be separated from the fin 203 by the gaps 255. As a result, the second nanosheets 216 are suspended. The opposite ends of the suspended second nanosheets 216 are connected to epitaxial features 240. In some embodiments, the suspended second nanosheets 216 may be referred to as “channel members” or “channel regions”. As shown in FIG. 18, the second nanosheets 216 separated from each and vertically stacked are referred to as a “stack of semiconductor nanosheets” or “stack of semiconductor channels” in some examples.

In some embodiments, a height of the gaps 255 may be about 5 nm to 30 nm. In the present embodiment, the second nanosheets 216 include silicon, and the first nanosheets 214 include silicon germanium. The first nanosheets 214 may be selectively removed by oxidizing the first nanosheets 214 using a suitable oxidizer, such as ozone. Thereafter, the oxidized first nanosheets 214 may be selectively removed from the gate trenches 254. In some embodiments, the etching process includes a dry etching process to selectively remove the first nanosheets 214, for example, by applying an HCl gas at a temperature of about 20° C. to about 300° C., or applying a gas mixture of CF₄, SF₆, and CHF₃.

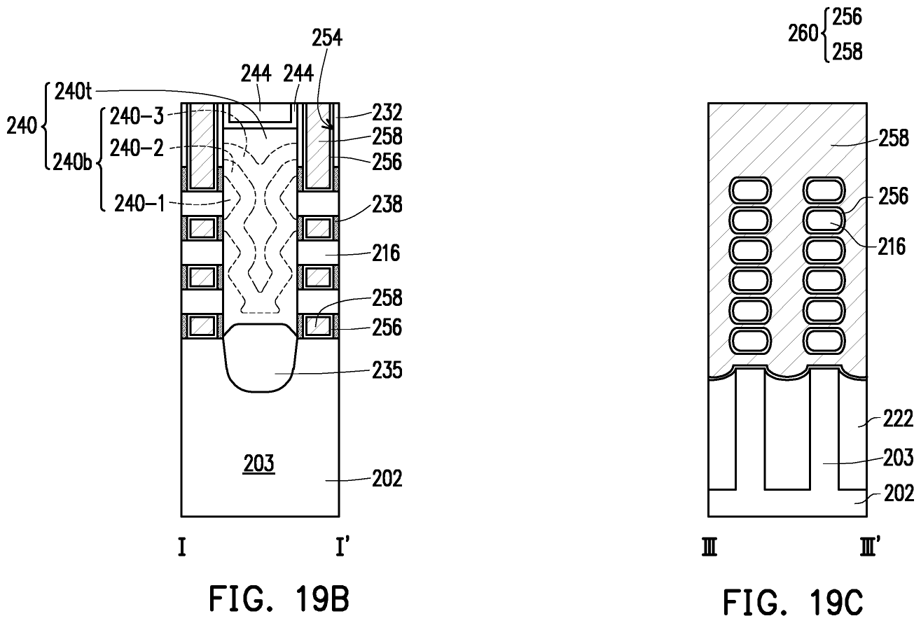

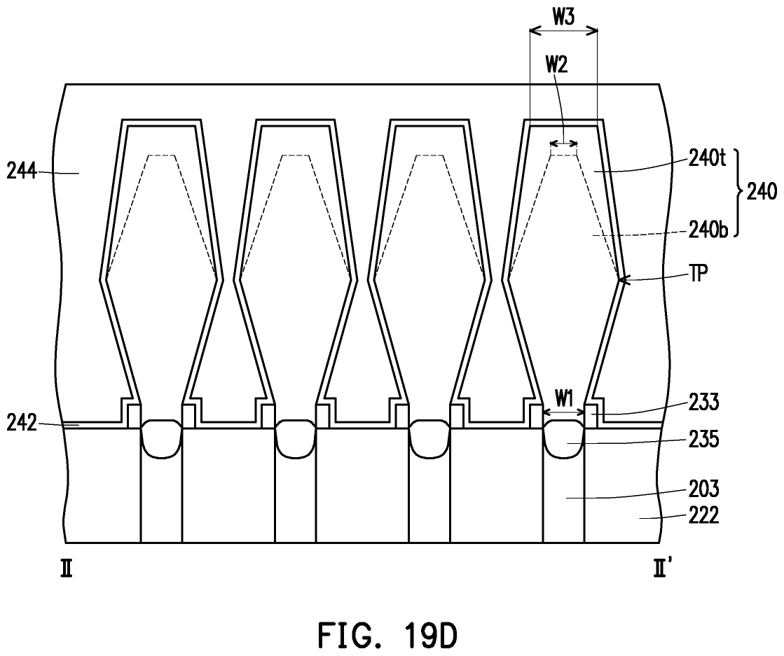

Referring to FIG. 19A, FIG. 19B, FIG. 19C and FIG. 19D, a gate dielectric layer 256 is formed in the gate trenches 254 and the gaps 255. In some embodiments, the gate dielectric layer 256 conformally covers each gate trench 254 to form a U-shape cross-section, and further conformally covers the surface of each gap 255 exposed to the gate trenches 254 to form a circle-like shape cross-section. In some embodiments, the gate dielectric layer 256 includes at least one dielectric material, such as a high-k material. Examples of the high-k material include metal oxide, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, the like, or combinations thereof. The high-k material has a dielectric constant less than 8, less than 15, less than 20, or even more. The gate dielectric layer 256 may be formed by CVD, ALD or a suitable method. In one embodiment, the gate dielectric layer 256 is formed by using a highly conformal deposition process, such as ALD in order to ensure the formation of a gate dielectric layer having a uniform thickness around each channel members. The thickness of the gate dielectric layer 256 is in a range from about 0.5 nm to about 3 nm in some embodiments.

In some embodiments, the gate dielectric layer 256 includes an interfacial layer (not shown) formed between each channel members and the high-k material. For example, the interfacial layer wraps each of the second nanosheets 216 in the channel regions. The interfacial layer may be deposited or thermally grown respectively on the second nanosheets 216 according to acceptable techniques, and made of, for example, silicon dioxide, a low-k dielectric material (e.g., a material having a dielectric constant lower than silicon dioxide), silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOₓC_{y}, Spin-On-Glass, Spin-On-Polymers, silicon carbon material, a compound thereof, a composite thereof, the like, or a combination thereof. The thickness of the interfacial layer is in a range from about 0.7 nm to about 2.5 nm in some embodiments.

Thereafter, a gate electrode 258 is formed on the gate dielectric layer 256 to surround each of the second nanosheets 216. In some embodiments, the gate electrode 258 completely fills the gate trenches 254 and the gaps 255. In some embodiments, the gate electrode 258 may include one or more conductive materials, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloy, a suitable material, or a combination thereof. The gate electrode 258 may be formed by CVD, ALD, electro-plating, or other suitable method. The gate dielectric layer 256 and the gate electrode 258 may also be deposited over the upper surfaces of the ILD layer 244 and the CESL 242. The gate dielectric layer 256 and the gate electrode 258 formed over the ILD layer 244 and the CESL 242 are then planarized by using, for example, CMP, until the top surfaces of the ILD layer 244 and the CESL 242 are revealed. In some embodiments, after the planarization operation, the gate electrode 258 is recessed and a cap insulating layer (not shown) is formed over the recessed gate electrode 258. The cap insulating layer includes one or more layers of a silicon nitride-based material, such as SiN. The cap insulating layer may be formed by depositing an insulating material followed by a planarization operation.

In other embodiments, one or more work function adjustment layers (not shown) are interposed between the gate dielectric layer 256 and the gate electrode 258. The work function adjustment layers are made of a conductive material, such as a single layer of TiN, TaN, TaAlC, TiC, TaC, Co, Al, TiAl, HfTi, TiSi, TaSi or TiAlC, or a multilayer of two or more of these materials. For the n-type device, one or more of TaN, TaAlC, TiN, TiC, Co, TiAl, HfTi, TiSi and TaSi is used as the work function adjustment layer, and for the p-type device, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-type device and the p-type device which may use different metal layers.

In some embodiments, the gate electrode 258 and the gate dielectric layer 256 constitute a gate structure 260. Upon the formation of the gate structure 260, a semiconductor device 200 of the embodiment is thus accomplished. In some embodiment, the liner layers 235 are configured to line the bottom surfaces of the epitaxial features 240. The liner layers 235 are beneficial for epitaxially growing the epitaxial features 240. In some embodiment, the adjacent epitaxial features 240 at the same side are formed to separate from each other with the novel epitaxial method with UV illumination of the disclosure. In the disclosure, the conventional blocking wall for prevent the adjacent epitaxial features 240 from merging is not required, and the shapes of the epitaxial features 240 are well controlled with the novel epitaxial method with UV illumination of the disclosure.

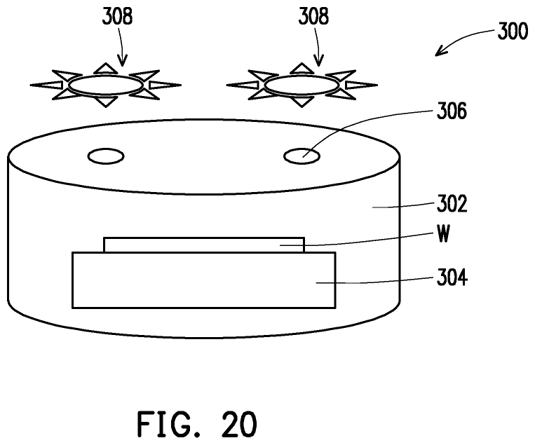

FIG. 20 is a schematic view of a semiconductor fabrication apparatus in accordance with some embodiments. In some embodiments, the semiconductor fabrication apparatus 300 is an epitaxial growth tool for forming the epitaxial features 240.

Referring to FIG. 20, a semiconductor fabrication apparatus 300 includes a chamber 302, within which a substrate or a wafer W can be disposed for performing an epitaxial growth. The chamber 302 may include an opaque material, such as UV quartz, IR glass, sapphire, UV-grade fused silica, or the like. In some embodiment, the chamber 302 may include other material such as steel. In order to introduce the UV radiation to the substrate or a wafer W, the chamber 302 is configured with windows 306. The windows 306 may be configured in line with the radiation from UV sources 308. The material of the windows 308 may include an opaque material, such as UV quartz, IR glass, sapphire, UV-grade fused silica, or the like. The windows 308 are optional and may be omitted as needed.

The chamber 202 includes a wafer holder or a platen 304. The platen 304 may include a wafer chuck, for example an e-chuck in some embodiments. The platen 304 is configured to hold or carry one or more of a substrate such as a semiconductor wafer.

In some embodiments, the semiconductor fabrication apparatus 300 includes a heating element providing thermal energy to and around the target substrate. In an embodiment, the heating element is a heating coil, for example, introducing heat from below the target substrate. In an embodiment, the heating element includes a plurality of lamps providing the thermal energy. The lamps may include IR lamps, tungsten-halogen lamps, and/or other suitable lamps. The thermal energy producing lamps may be disposed in an array and/or be single spot lamps. The heating element may provide an elevated temperature at the platen 304 and to a target substrate disposed on the platen 304. The elevated temperature may be identified and controlled by temperature reading devices (e.g., thermocouples) and control loops for temperature control. The heating device or devices may provide for heat to be introduced to the top side of the target substrate and/or the bottom side of the target substrate or platen 304. In some embodiments, the epitaxial temperature ranges from 200° C. to 1,000° C. In some embodiments, the epitaxial pressure ranges from about 1 mTorr to 1,000 Torr.

The semiconductor fabrication apparatus 300 includes UV sources 308. The UV sources 308 may each include a UV lamp and a reflector. The UV lamp may include VIS, UV-A, UV-B, UV-C, Gallium, Iron, Mercury, or the like, and the reflector may have high UV reflectance and highly resistant to corrosion, such as aluminum, copper, rhodium, silver, gold, platinum, or an alloy thereof. The UV sources 308 may have a wavelength of about 100 nm to 615 m with a proton energy between about 2.0 eV to 12.4 eV. The UV sources 308 may each include a laser such as semiconductor, Argon, Xenon, Nitrogen or Excimer lasers. The source (lamp/laser) power may range from about zero to 10,000 W/m2, may be continuous wave or pulsed, may have the option of turning on and off during the epitaxial process, and may or may not be polarized.

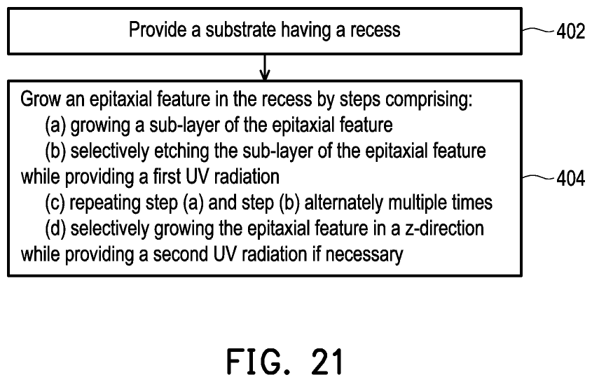

FIG. 21 illustrates a flow chart of a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 402, a substrate is provided with a recess. FIG. 1 to FIG. 9B illustrate perspective and cross-sectional views corresponding to some embodiments of act 402. The above embodiments in which the substrate is a substrate for forming a GAA device are provided for illustration purposes, and are not construed as limiting the present disclosure. In other embodiments, the substrate is a substrate for forming a FinFET device. In other embodiments, the substrate is a substrate for forming a planar device.

At act 404, an epitaxial feature is grown in the recess by steps including: (a) growing a sub-layer of the epitaxial feature; (b) selectively etching the sub-layer of the epitaxial feature while providing a first UV radiation; (c) repeating step (a) and step (b) alternately multiple times; and selectively growing the epitaxial feature in a z-direction while providing a second UV radiation if necessary. FIG. 10 to FIG. 15C illustrate perspective and cross-sectional views corresponding to some embodiments of act 402. In some embodiments, the first UV radiation is provided at a direction normal to a top surface of the substrate, as shown in FIG. 11 and FIG. 13. In some embodiments, an upper portion of the sub-layer of the epitaxial feature is etched more than a lower portion of the sub-layer of the epitaxial feature, as shown in FIG. 11 and FIG. 13. In some embodiments, after step (c), a top width of the epitaxial feature is less than a bottom width of the epitaxial feature, as shown in FIG. 14C. In some embodiments, the epitaxial feature is grown in the recess by steps further including (d) selectively growing the epitaxial feature in a z-direction while providing a second UV radiation after step (c), as shown in FIG. 15A to FIG. 15D. In some embodiments, the second UV radiation is provided at a direction normal to a top surface of the substrate, as shown in FIG. 15B to FIG. 15C. In some embodiments, after step (d), a top width of the epitaxial feature is substantially equal to or greater than a bottom width of the epitaxial feature, as shown in FIG. 15C. In some embodiments, a liner layer is further formed between the substrate and the epitaxial feature, as shown in FIG. 10.

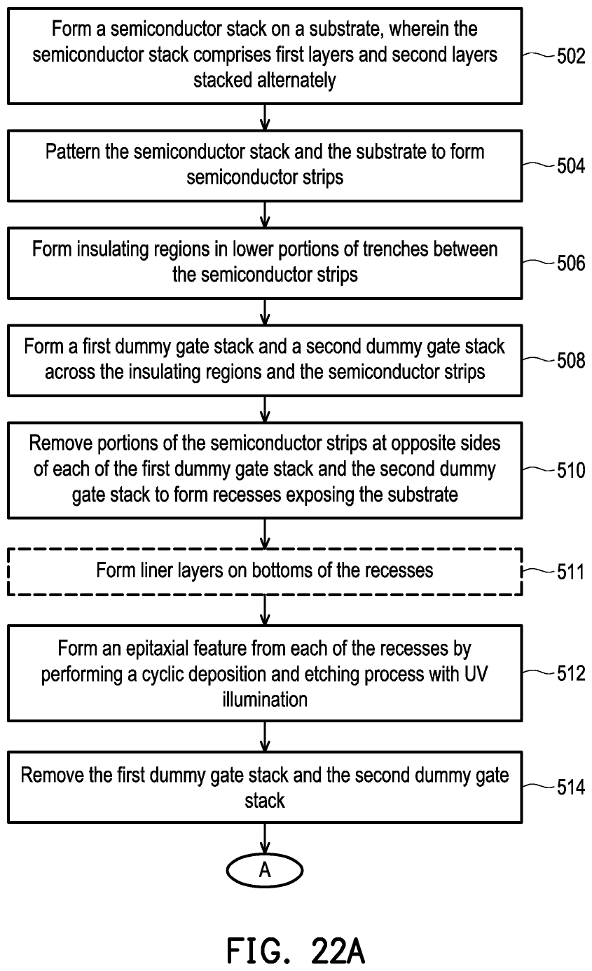

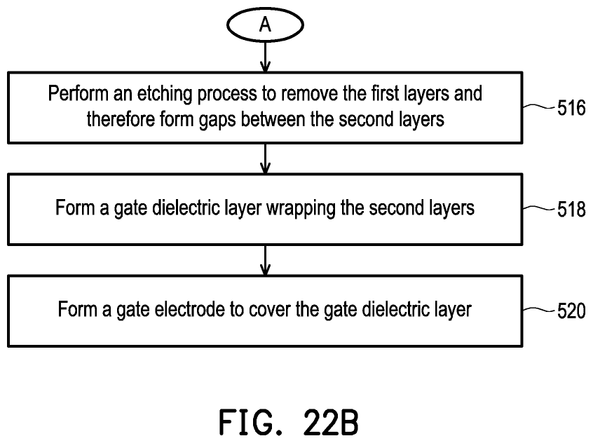

FIG. 22A to FIG. 22B illustrate a flow chart of a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 502, a semiconductor stack is formed on a substrate, wherein the semiconductor stack includes first layers and second layers stacked alternately. FIG. 1 illustrates a perspective view corresponding to some embodiments of act 502.

At act 504, the semiconductor stack and the substrate are patterned to form semiconductor strips. FIG. 1 to FIG. 2 illustrate perspective views corresponding to some embodiments of act 504.

At act 506, insulating regions are formed in lower portions of trenches between the semiconductor strips. FIG. 3 to FIG. 4 illustrate perspective views corresponding to some embodiments of act 506.

At act 508, a first dummy gate stack and a second dummy gate stack are formed across the insulating regions and the semiconductor strips. FIG. 5 illustrates a perspective view corresponding to some embodiments of act 508.

At act 510, portions of the semiconductor strips at opposite sides of each of the first dummy gate stack and the second dummy gate stack are removed to form recesses exposing the substrate. FIG. 6A to FIG. 7B illustrate perspective and cross-sectional views corresponding to some embodiments of act 510.

At act 511, liner layers are formed on bottoms of the recesses. FIG. 10 illustrates a cross-sectional view corresponding to some embodiments of act 511. Act 511 is optional and may be omitted as needed. In some embodiments, when act 511 is omitted from the method, the subsequently formed stained layers are in direct contact with fins protruding from the substrate.

At act 512, an epitaxial feature is formed from each of the recesses by performing a cyclic deposition and etching process with UV illumination. FIG. 10 to FIG. 15C illustrate perspective and cross-sectional views corresponding to some embodiments of act 512.

In some embodiments, the cyclic deposition and etching process includes: (a) growing a sub-layer of the epitaxial feature in each of the recesses; (b) selectively etching the sub-layer of the epitaxial feature while providing a first UV radiation; and (c) repeating step (a) and step (b) alternately multiple times, until each of the recesses is filled with the sub-layers. In some embodiments, the first UV radiation ranges from about 100 nm to 615 nm. In some embodiments, the cyclic deposition and etching process further includes: (d) selectively growing the epitaxial feature in a z-direction while providing a second UV radiation after step (c). In some embodiments, the second UV radiation is different from the first UV radiation. In some embodiments, the second UV radiation is the same as the first UV radiation. In some embodiments, the second UV radiation ranges from about 100 nm to 615 nm.

In some embodiments, a cycle of the cyclic deposition and etching process includes: (a) growing a sub-layer of the epitaxial feature in each of the recesses with a first UV power; (b) selectively etching the sub-layer of the epitaxial feature while providing a second UV power different from the first UV power; and (c) repeating step (a) and step (b) alternately multiple times, until each of the recesses is filled with the sub-layers. In some embodiments, the first UV power ranges from zero to 10 W/m², and second UV power ranges from 10 W/m² to 10,000 W/m².

At act 514, the first dummy gate stack and the second dummy gate stack are removed. FIG. 16 to FIG. 18 illustrate cross-sectional views corresponding to some embodiments of act 514.

At act 516, an etching process to remove the first layers and therefore form gaps between the second layers. FIG. 18 illustrates a cross-sectional view corresponding to some embodiments of act 516.

At act 518, a gate dielectric layer is formed to wrap the second layers. FIG. 19A to FIG. 19D illustrate perspective and cross-sectional views corresponding to some embodiments of act 518.

At act 520, a gate electrode is formed to cover the gate dielectric layer. FIG. 19A to FIG. 19D illustrate perspective and cross-sectional views corresponding to some embodiments of act 520.

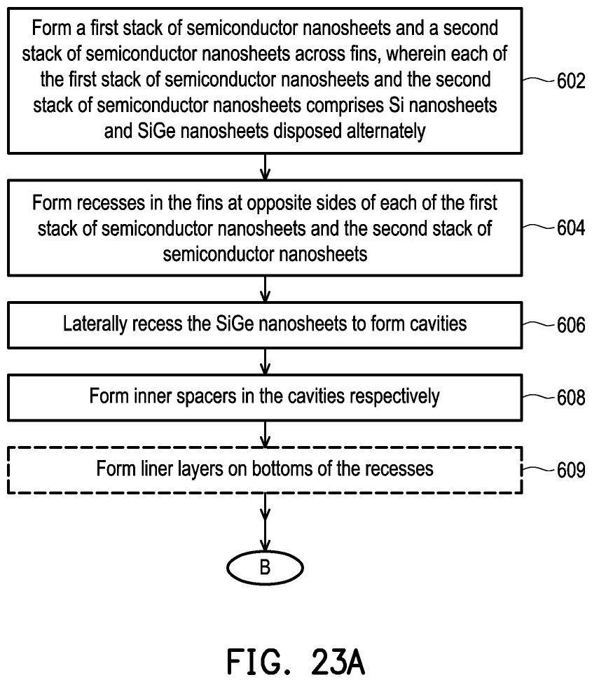

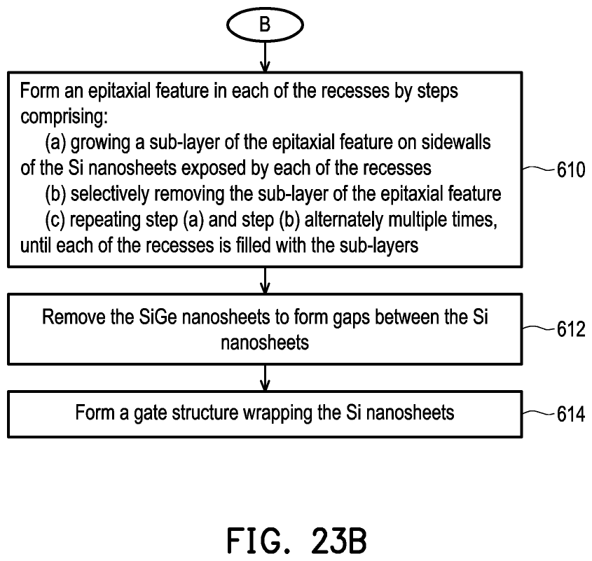

FIG. 23A to FIG. 23B illustrate a flow chart of a method of forming a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 602, a first stack of semiconductor nanosheets and a second stack of semiconductor nanosheets are formed across fins, wherein each of the first stack of semiconductor nanosheets and the second stack of semiconductor nanosheets includes Si nanosheets and SiGe nanosheets disposed alternately. FIG. 1 to FIG. 4 illustrate perspective views corresponding to some embodiments of act 602.

At act 604, recesses are formed in the fins at opposite sides of each of the first stack of semiconductor nanosheets and the second stack of semiconductor nanosheets. FIG. 5 to FIG. 7B illustrate perspective and cross-sectional views corresponding to some embodiments of act 604.

At act 606, the SiGe nanosheets are laterally recessed to form cavities. FIG. 8A to FIG. 8B illustrate perspective and cross-sectional views corresponding to some embodiments of act 606.

At act 608, inner spacers are formed in the cavities respectively. FIG. 9A to FIG. 9B illustrate perspective and cross-sectional views corresponding to some embodiments of act 608.

At act 609, liner layers are formed on bottoms of the recesses. FIG. 10 illustrates a cross-sectional view corresponding to some embodiments of act 609. Act 609 is optional and may be omitted as needed.

At act 610, an epitaxial feature is formed in each of the recesses by steps including: (a) growing a sub-layer of the epitaxial feature on sidewalls of the Si nanosheets exposed by each of the recesses; (b) selectively removing the sub-layer of the epitaxial feature; and (c) repeating step (a) and step (b) alternately multiple times, until each of the recesses is filled with the sub-layers. FIG. 10 to FIG. 15C illustrate perspective and cross-sectional views corresponding to some embodiments of act 610. In some embodiments, step (b) includes providing a UV radiation, so as to remove more sub-layer of the epitaxial layer in an upper portion of the recess while remove less sub-layer of the epitaxial layer in a lower portion of the recess, as shown in FIG. 11 and FIG. 13.

At act 612, the SiGe nanosheets are removed to form gaps between the Si nanosheets. FIG. 16 to FIG. 18 illustrates cross-sectional views corresponding to some embodiments of act 612

At act 614, a gate structure is formed to wrap the Si nanosheets. FIG. 19A to FIG. 19D illustrate perspective and cross-sectional views corresponding to some embodiments of act 614.

In some embodiments of the disclosure, the adjacent epitaxial features at the same side are formed to separate from each other with the novel epitaxial method with UV illumination of the disclosure. In the disclosure, the conventional blocking wall for prevent the adjacent epitaxial features from merging is not required, and the shapes of the epitaxial features are well controlled with the novel epitaxial method with UV illumination of the disclosure. Accordingly, epitaxial strained features with fewer merge defect and better device performance are provided.

According to some embodiments, a method of forming a semiconductor device includes providing a substrate having a recess, and growing an epitaxial feature in the recess. The method of growing the epitaxial feature includes: (a) growing a sub-layer of the epitaxial feature; (b) selectively etching the sub-layer of the epitaxial feature while providing a first UV radiation; and (c) repeating step (a) and step (b) alternately multiple times.

According to some embodiments, a method of forming a semiconductor device includes: forming a semiconductor stack on a substrate, wherein the semiconductor stack includes first layers and second layers stacked alternately; patterning the semiconductor stack and the substrate to form semiconductor strips; forming insulating regions in lower portions of trenches between the semiconductor strips; forming a first dummy gate stack and a second dummy gate stack across the insulating regions and the semiconductor strips; removing portions of the semiconductor strips at opposite sides of each of the first dummy gate stack and the second dummy gate stack to form recesses exposing the substrate; and forming an epitaxial feature from each of the recesses by performing a cyclic deposition and etching process with UV illumination.

According to some embodiments, a method of forming a semiconductor device includes: forming a first stack of semiconductor nanosheets and a second stack of semiconductor nanosheets across fins, wherein each of the first stack of semiconductor nanosheets and the second stack of semiconductor nanosheets includes Si nanosheets and SiGe nanosheets disposed alternately; forming recesses in the fins at opposite sides of each of the first stack of semiconductor nanosheets and the second stack of semiconductor nanosheets; laterally recessing the SiGe nanosheets to form cavities; forming inner spacers in the cavities respectively; and forming an epitaxial feature in each of the recesses, wherein the forming includes: (a) growing a sub-layer of the epitaxial layer on sidewalls of the Si nanosheets exposed by each of the recesses; (b) selectively removing the sub-layer of the epitaxial layer; and (c) repeating step (a) and step (b) alternately multiple times, until each of the recesses is filled with the sub-layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
providing a substrate having a recess; and
growing an epitaxial feature in the recess, wherein the growing comprises:
(a) growing a sub-layer of the epitaxial feature;
(b) selectively etching the sub-layer of the epitaxial feature while providing a first UV radiation; and
(c) repeating step (a) and step (b) alternately multiple times.

2. The method of claim 1, wherein the first UV radiation is provided at a direction normal to a top surface of the substrate.

3. The method of claim 1, wherein an upper portion of the sub-layer of the epitaxial feature is etched more than a lower portion of the sub-layer of the epitaxial feature in step (b).

4. The semiconductor device of claim 1, wherein after step (c), a top width of the epitaxial feature is less than a bottom width of the epitaxial feature.

5. The method of claim 1, wherein the growing further comprises:
(d) selectively growing the epitaxial feature in a z-direction while providing a second UV radiation after step (c).

6. The method of claim 5, wherein the second UV radiation is provided at a direction normal to a top surface of the substrate.

7. The method of claim 5, wherein after step (d), a top width of the epitaxial feature is substantially equal to or greater than a bottom width of the epitaxial feature.

8. The semiconductor device of claim 1, further comprising forming a liner layer between the substrate and the epitaxial feature.

9. A method of forming a semiconductor device, comprising:
forming a semiconductor stack on a substrate, wherein the semiconductor stack comprises first layers and second layers stacked alternately;
patterning the semiconductor stack and the substrate to form semiconductor strips;
forming insulating regions in lower portions of trenches between the semiconductor strips;
forming a first dummy gate stack and a second dummy gate stack across the insulating regions and the semiconductor strips;
removing portions of the semiconductor strips at opposite sides of each of the first dummy gate stack and the second dummy gate stack to form recesses exposing the substrate; and
forming an epitaxial feature from each of the recesses by performing a cyclic deposition and etching process with UV illumination.

10. The method of claim 9, wherein the cyclic deposition and etching process comprises:
(a) growing a sub-layer of the epitaxial feature in each of the recesses;
(b) selectively etching the sub-layer of the epitaxial feature while providing a first UV radiation; and
(c) repeating step (a) and step (b) alternately multiple times, until each of the recesses is filled with the sub-layers.

11. The method of claim 10, wherein the first UV radiation ranges from about 100 nm to 615 nm.

12. The method of claim 10, wherein the cyclic deposition and etching process further comprises:
(d) selectively growing the epitaxial feature in a z-direction while providing a second UV radiation after step (c).

13. The method of claim 12, wherein the second UV radiation is different from the first UV radiation.

14. The method of claim 12, wherein the second UV radiation is the same as the first UV radiation.

15. The method of claim 12, wherein the second UV radiation ranges from about 100 nm to 615 nm.

16. The method of claim 9, wherein a cycle of the cyclic deposition and etching process comprises:
(a) growing a sub-layer of the epitaxial feature in each of the recesses with a first UV power;
(b) selectively etching the sub-layer of the epitaxial feature while providing a second UV power different from the first UV power; and
(c) repeating step (a) and step (b) alternately multiple times, until each of the recesses is filled with the sub-layers.

17. The method of claim 16, wherein the first UV power ranges from zero to 10 W/m², and second UV power ranges from 10 W/m² to 10,000 W/m².

18. The method of claim 9, further comprising:
removing the first dummy gate stack and the second dummy gate stack;
performing an etching process to remove the first layers and therefore form gaps between the second layers;
forming a gate dielectric layer wrapping the second layers; and
forming a gate electrode to cover the gate dielectric layer.

19. A method of forming a semiconductor device, comprising:
forming a first stack of semiconductor nanosheets and a second stack of semiconductor nanosheets across fins, wherein each of the first stack of semiconductor nanosheets and the second stack of semiconductor nanosheets comprises Si nanosheets and SiGe nanosheets disposed alternately;
forming recesses in the fins at opposite sides of each of the first stack of semiconductor nanosheets and the second stack of semiconductor nanosheets;
laterally recessing the SiGe nanosheets to form cavities;
forming inner spacers in the cavities respectively; and
forming an epitaxial feature in each of the recesses, wherein the forming comprises:
(a) growing a sub-layer of the epitaxial layer on sidewalls of the Si nanosheets exposed by each of the recesses;
(b) selectively removing the sub-layer of the epitaxial layer; and
(c) repeating step (a) and step (b) alternately multiple times, until each of the recesses is filled with the sub-layers.

20. The method of claim 19, wherein step (b) comprises providing a UV radiation, so as to remove more sub-layer of the epitaxial layer in an upper portion of the recess while remove less sub-layer of the epitaxial layer in a lower portion of the recess.
